(19) United States
(12) Patent Application Publication
(10) Pub. No.: US 2025/0045904 A1
(43) Pub. Date: Feb. 6, 2025

(54) IMAGE SEGMENTATION FOR EXAMINING A SEMICONDUCTOR SPECIMEN

(71) Applicant: Applied Materials Israel Ltd., Rehovot (IL)

(72) Inventors: Gilad VERED, Shoam (IL); Dror ALUMOT, Tel-Aviv (IL); Rafael BISTRITZER, Petach Tikva (IL); Hadar SHLOMAI-NAPARSTEK, Tzofim (IL); Yarden ZOHAR, Holon (IL)

(21) Appl. No.: 18/230,127

(22) Filed: Aug. 3, 2023

(51) Int. Cl. G06T 7/00; G06T 7/10; G06T 7/50; G06V 10/46; G06V 10/764

(52) U.S. Cl. CPC G06T 7/0008; G06T 7/10; G06T 7/50; G06V 10/46; G06V 10/764; G06T 2207/20036; G06T 2207/30148

(57) ABSTRACT

A system for examining a semiconductor specimen that includes a plurality of layers at respective different depths, and a plurality of holes. Each hole has a top portion at the surface of the specimen, and a bottom portion accommodated in one of the layers. The system includes a processing and memory circuitry (PMC) configured to provide an inspection image indicative of the holes, and process a hole image in the inspection image, without using a shape characterizing model. The processing includes segmenting the inspection image and determining data indicative of a contour of the top portion of the hole, and further segmenting the inspection image and determining data indicative of a contour of a shape enclosed within the contour of the top of the hole.

### TECHNICAL FIELD

The presently disclosed subject matter relates, in general, to the field of image segmentation for examining a semiconductor specimen.

### BACKGROUND

Current demands for high density and performance associated with ultra large-scale integration of fabricated devices require submicron features, increased transistor and circuit speeds, and improved reliability. As semiconductor processes progress, pattern dimensions, such as line width, and other types of critical dimensions, are continuously shrunken. Such demands require formation of device features with high precision and uniformity, which, in turn, necessitates careful monitoring of the fabrication process, including automated examination of the devices while they are still in the form of semiconductor wafers.

Examination can be provided by using non-destructive examination tools during or after manufacture of the specimen to be examined. Examination generally involves generating certain output (e.g., images, signals, etc.) for a specimen by directing light or electrons to the wafer and detecting the light or electrons from the wafer. A variety of non-destructive examination tools includes, by way of non-limiting example, scanning electron microscopes, atomic force microscopes, optical inspection tools, etc.

Examination processes can include a plurality of examination steps. The manufacturing process of a semiconductor device can include various procedures such as etching, depositing, planarization, growth such as epitaxial growth, implantation, etc. The examination steps can be performed a multiplicity of times, for example after certain process procedures, and/or after the manufacturing of certain layers, or the like. Additionally, or alternatively, each examination step can be repeated multiple times, for example for different wafer locations, or for the same wafer locations with different examination settings.

Examination processes are used at various steps during semiconductor fabrication for performing metrology related operations and/or defect related operations. Effectiveness of examination can be improved by automatization of certain process(es) such as, for example, defect detection, Automatic Defect Classification (ADC), Automatic Defect Review (ADR), image segmentation, and automated metrology-related operations, etc. Automated examination systems ensure that the parts manufactured meet the quality standards expected and provide useful information on adjustments that may be needed to the manufacturing tools, equipment, and/or compositions, depending on the type of errors identified, so as to promote higher yield.

### SUMMARY

In accordance with certain aspects of the presently disclosed subject matter, there is provided a system for examining a semiconductor specimen comprising a plurality of layers at respective different depths, and a plurality of holes, each hole having a top portion at the surface of the specimen and a bottom portion accommodated in one of the layers, the system comprising a processing and memory circuitry (PMC) configured to:
a. provide an inspection image indicative of at least one of the holes;
b. process at least one hole image in the inspection image, including:
   i. segment the inspection image and determine data indicative of a contour of the top portion of the hole;
   ii. segment the inspection image or derivative thereof and determine data indicative of a contour of a shape of the bottom of said hole enclosed within the contour of the top of the hole; wherein said segmenting includes classifying the image into at least two clusters of pixels having discernable pixel values one with respect to the other, and determining the data indicative of the contour of said shape based on the pixel values of one of said clusters;
   thereby facilitating examining of the specimen including utilizing at least the data indicative of the contour of the shape of the bottom of the hole, for measurements of characteristics of at least the hole bottom.

In addition to the above features, the system according to this aspect of the presently disclosed subject matter can comprise one or more of features (i) to (ix) listed below, in any desired combination or permutation which is technically possible:
(i) wherein the semiconductor specimen is a staircase 3DNAND, and wherein the hole is a High Aspect Ratio (HAR) Via, and wherein the bottom portion is accommodated in a Tungsten layer of said specimen.
(ii) wherein the segmenting stipulated in said (b) (ii), does not use a shape characterizing model.
(iii) wherein the PMC is further configured to segment the image, including: applying at least two iterations of KMeans function, where K>2 in the first iteration, followed by a descending K in each next iteration, and K=2 in the last iteration, giving rise to an image having at least two clusters of pixels characterized by discernable pixel values, one with respect to the other, wherein the data indicative of the contour of the shape is determined based on the pixel values of one of the clusters.
(iv) wherein the computerized system includes two iterations, and wherein K=3 in the first iteration, and K=2 in the second iteration.
(v) wherein said PMC is further configured to apply a smoothing operation between at least two of the iterations.
(vi) wherein the PMC is further configured to apply at least one morphological operation following the last iteration, for obtaining data indicative of a different contour representing a corrected shape of the bottom of the hole.
(vii) wherein said PMC is further configured to determine data indicative of the contour of the top portion of the hole, such that peripheral pixels are excluded, and then applying the at least two iterations; wherein the peripheral pixels are pixels at the periphery of the hole having pixel values indicative of brighter pixels compared to pixels in their vicinity.
(viii) wherein the shape characterizing model characterizes geometrical shapes obtained from at least an a-priori design or drawing, and used for determining a sought shape or shapes.
(ix) measuring at least one of the following characteristics of hole top or bottom:
   CD—fit contour to ellipse and calculate 2*sqrt (major_axis*minor axis).
   Area—fit contour to ellipse and calculate its area.
   GL—grey level statistics such as average and std.
      Slant is between top and bottom COGs (Center of Gravity):
Direction—angle between the vector connecting COGs and X axis.
Length—Euclidian distance between COGs.

In accordance with other aspects of the presently disclosed subject matter, there is provided a computerized method for examining a semiconductor specimen comprising a plurality of layers at respective different depths and a plurality of holes, each hole having a top portion at the surface of said specimen and a bottom portion accommodated in one of the layers, the method comprising by a processor and memory circuitry (PMC):
a. providing an inspection image indicative of at least one of said holes;
b. processing at least one hole image in said image, including:
   i. segmenting the inspection image and determining data indicative of a contour of the top portion of the hole;
   ii. segmenting the inspection image or derivative thereof and determining data indicative of a contour of a shape enclosed within the contour of the top of the hole, without using a shape characterizing model;
   thereby facilitating examining of the specimen including utilizing at least the data indicative of the contour of the shape of the bottom of said hole, for measurements of characteristics of at least the hole bottom.

This aspect of the disclosed subject matter can comprise one or more of features (i), (iii) to (ix) listed above with respect to the system as well as (x) wherein said segmenting includes classifying the image into at least two clusters of pixels having discernable pixel values one with respect to the other, and determining the data indicative of the contour of said shape based on the pixel values of one of said clusters; mutatis mutandis, wherein said features (i), (iii) to (ix) and (x) can be utilized in any desired combination or permutation which is technically possible.

In accordance with other aspects of the presently disclosed subject matter, there is provided a non-transitory computer readable storage medium tangibly embodying a program of instructions that, when executed by a computer, cause the computer to perform a method for examining a semiconductor specimen comprising a plurality of layers at respective different depths and a plurality of holes, each hole having a top portion at the surface of the specimen and a bottom portion accommodated in one of the layers, the method comprising:
a. providing an inspection image indicative of at least one of the holes;
b. processing at least one hole image in the image, including:
   i. segmenting the inspection image and determining data indicative of a contour of the top portion of the hole;
   ii. segmenting the inspection image or derivative thereof and determining data indicative of a contour of a shape enclosed within the contour of the top of the hole, without using a shape characterizing model,
   thereby facilitating examining of the specimen including utilizing at least the data indicative of the contour of the shape of the bottom of the hole, for measurements of characteristics of at least the hole bottom.

This aspect of the disclosed subject matter can comprise one or more of features (i), (iii) to (ix) listed above with respect to the system as well as (x) wherein said segmenting includes classifying the image into at least two clusters of pixels having discernable pixel values one with respect to the other, and determining the data indicative of the contour of said shape based on the pixel values of one of said clusters; mutatis mutandis, wherein said features (i), (iii) to (ix) and (x) can be utilized in any desired combination or permutation which is technically possible.

### BRIEF DESCRIPTION OF THE DRAWINGS

The patent or application file contains at least one drawing executed in color. Copies of this patent or patent application publication with color drawing(s) will be provided by the Office upon request and payment of the necessary fee.

In order to understand the disclosure and to see how it may be carried out in practice, embodiments will now be described, by way of non-limiting example only, with reference to the accompanying drawings, in which:

FIG. 1 illustrates a generalized block diagram of an examination system in accordance with certain embodiments of the presently disclosed subject matter;

FIG. 2 illustrates schematically a semiconductor staircase 3DNAND specimen with a plurality of High Aspect Ratio (HAR) Vias;

FIG. 3 illustrates schematically a plurality of contours in images indicative of corresponding different shapes of hole bottoms, in a semi-conductor specimen, in accordance with certain embodiments of the presently disclosed subject matter;

FIG. 4 illustrates a generalized flowchart of a model-less sequence of operations, for segmenting an image, and determining a contour of a shape of a bottom of a hole in a semiconductor specimen, in accordance with certain embodiments of the presently disclosed subject matter;

FIG. 5 illustrates a more specific flowchart of a model-less sequence of operations, for segmenting an image and determining a contour of a shape of a bottom of a hole in a semiconductor specimen, in accordance with certain embodiments of the presently disclosed subject matter;

FIG. 6 is a graphic illustration of the sequence of operations depicted in FIG. 4, in accordance with certain embodiments of the presently disclosed subject matter;

FIG. 7A illustrates, schematically, a generalized flowchart of removing a bright ring in an image, in accordance with certain embodiments of the presently disclosed subject matter;

FIG. 7B illustrates, schematically, an auxiliary data structure used in the process of removing “bright” pixels, in accordance with certain embodiments of the presently disclosed subject matter;

FIGS. 8A-B illustrate, schematically, a plurality of images, obtained as a result of applying first and second Kmeans iterations, in accordance with certain embodiments of the presently disclosed subject matter;

FIG. 9 illustrates, schematically, images obtained as a result of applying a Gaussian smoothing, in accordance with certain embodiments of the presently disclosed subject matter; and

FIG. 10 illustrates, schematically, an image indicative of a shape of the bottom of a hole in a semi-conductor specimen, obtained as a result of applying a contour correction operation, in accordance with certain embodiments of the presently disclosed subject matter.

### DETAILED DESCRIPTION OF EMBODIMENTS

A semiconductor specimen (e.g., a staircase 3DNAND specimen) may include a plurality of layers at respective different depths, and a plurality of holes. The holes may have different hole bottom shapes, stemming, among others, from the HAR (High Aspect Ratio) characteristic of the holes. The specified HAR characteristics may affect the etching process, leading to the specified shape difference between different bottoms. Accurate determining of the shape of the holes' bottoms may be required for various purposes, such as defect inspection/detection, defect classification, segmentation, etc. However, considering the wide range variance among different possible bottom shapes, it is difficult to accurately determine the bottom shapes.

Hence, in accordance with certain embodiments of the invention there is provided a system (and corresponding method) for examining a semiconductor specimen that includes a plurality of layers at respective different depths and a plurality of holes. Each hole has a top portion at the surface of the specimen and a bottom portion accommodated in one of the layers. The system includes a processing and memory circuitry (PMC) configured to provide an inspection image indicative of the holes, and process a hole image in the inspection image, without using a shape characterizing model. The processing may include segmenting the inspection image and determining data indicative of a contour of the top portion of the hole, and further segmenting the inspection image and determining data indicative of a contour of a shape of a bottom of the hole enclosed within the contour of the top of the hole, thereby facilitating examining of the specimen, including utilizing the data indicative of the contour of the shape of the bottom of the hole, e.g. for measurements of characteristics of at least the hole bottom.

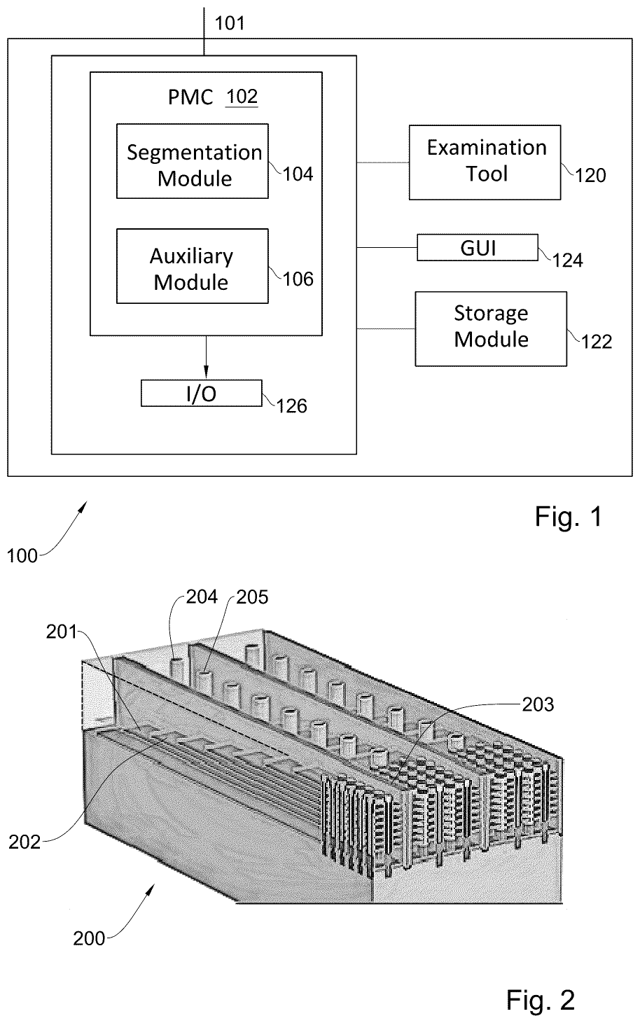

Bearing this in mind, attention is drawn to FIG. 1 illustrating a functional block diagram of an examination system in accordance with certain embodiments of the presently disclosed subject matter.

The examination system 100 illustrated in FIG. 1 can be used for examination of a semiconductor specimen (e.g., a wafer, a die, or parts thereof) as part of the specimen fabrication process. As described above, the examination referred to herein can be construed to cover any kind of operations related to defect inspection/detection, defect classification, segmentation, and/or metrology operations, such as, e.g., critical dimension (CD) measurements, overlay, etc., with respect to the specimen. System 100 comprises one or more examination tools 120 configured to scan a specimen and capture images thereof to be further processed for various examination applications.

The term “examination tool(s)” used herein should be expansively construed to cover any tools that can be used in examination-related processes, including, by way of non-limiting example, scanning (in a single or in multiple scans), imaging, sampling, reviewing, measuring, classifying, and/or other processes provided with regard to the specimen or parts thereof.

Without limiting the scope of the disclosure, it should also be noted that the examination tools 120 can be implemented as inspection machines of various types, such as optical inspection machines, electron beam inspection machines (e.g., Scanning Electron Microscope (SEM), Atomic Force Microscopy (AFM), or Transmission Electron Microscope (TEM), etc.), and so on. In some cases, the same examination tool can provide low-resolution image data and high-resolution image data. The resulting image data (low-resolution image data and/or high-resolution image data) can be transmitted-directly or via one or more intermediate systems—to system 101. The present disclosure is not limited to any specific type of examination tools and/or the resolution of image data resulting from the examination tools.

In some embodiments, at least one of the examination tools 120 has metrology capabilities and can be configured to capture images and perform metrology operations on the captured images. Such an examination tool is also referred to herein as a metrology tool.

According to certain embodiments, the metrology tool can be an electron beam tool, such as, e.g., a scanning electron microscope (SEM). SEM is a type of electron microscope that produces images of a specimen by scanning the specimen with a focused beam of electrons. The electrons interact with atoms in the specimen, producing various signals that contain information on the surface topography and/or composition of the specimen. SEM is capable of accurately measuring features during the manufacture of semiconductor wafers. By way of example, the metrology tool can be critical dimension scanning electron microscopes (CD-SEM) configured to perform metrology operations with respect to the structural features of a specimen based on the captured images.

It is to be noted that, the term “image(s)” used herein can refer to original images of the specimen captured by the examination tool during the manufacturing process, derivatives of the captured images obtained by various pre-processing stages, and/or computer-generated design data-based images. It is to be noted that in some cases the images referred to herein can include image data (e.g., captured images, processed images, etc.) and associated numeric data (e.g., metadata, hand-crafted attributes, etc.). It is further noted that image data can include data related to one or more layers of interest of the specimen.

The process of semiconductor manufacturing often requires fabricating a series of layers, at least some of which comprise various structural features (also referred to as structures or features) manufactured by one or more processing steps (also referred to as process steps). A structural feature can refer to an element or module to be manufactured on a layer that has a specific designed structure and functionality. Metrology operations can be performed at various processing steps during the manufacturing process to provide measurements for purposes of monitoring and controlling the process. Such measurements can include, for example, critical dimension (CD) measurements, overlay measurements, CD uniformity (CDU) measurements, etc.

In some cases, the measurements can be obtained based on image segmentation which delivers critical information on the shapes and dimensions of the structural features in the images, such as those indicative of holes. For instance, the images (indicative of holes in different layers) can be segmented for the purpose of identifying a contour of the top portion of the hole and contour of the shape that is representative of the bottom portion the hole (which, as will be explained in greater detail, may vary from one hole to the other). Once identifying the contours, various measurements can be applied. In such cases, the quality of the measurements may depend also on the performance of the image segmentation.

Accordingly, in certain embodiments of the presently disclosed subject matter there is provided a specimen that includes a plurality of layers at respective different depths, and a plurality of holes. Each hole has a top portion at the surface of the specimen, and a bottom portion accommodated in one of said layers, all as will be described, e.g., with reference to FIG. 2 below. Certain embodiments propose a method and system capable of accurately determining data indicative of the contours of shapes of bottom of holes, thus facilitating examination of the specimen, e.g., measuring various characteristics of the hole and/or the hole bottom.

According to certain embodiments of the presently disclosed subject matter, the examination system 100 comprises a computer-based system 101 operatively connected to the examination tools 120 and capable of segmenting acquired images and determining determinate shapes and contours of holes.

Specifically, system 101 includes a processor and memory circuitry (PMC) 102 operatively connected to a hardware-based I/O interface 126. The PMC 102 is configured to provide processing necessary for operating the system, as further detailed with reference to FIGS. 2 to 10, and comprises one or more processors (not shown separately) operatively connected to a memory (not shown separately). The processor(s) of PMC 102 can be configured to execute several functional modules in accordance with computer-readable instructions implemented on a non-transitory computer-readable memory comprised in the PMC. Such functional modules are referred to hereinafter as comprised in the PMC.

Functional modules comprised in the PMC 102 of system 101 can include, e.g., a segmentation and counter determination module 104, and auxiliary module 106.

The PMC 102 can be configured to obtain, via the I/O interface 126 and from the examination tool 120, an inspection image (an image indicative of at least one of the holes and possibly other data) of the semiconductor specimen in runtime. The image can be acquired by one (or more) tools, (e.g., the known per se VeritySEM tool). The invention is not bound by this example. The segmentation and contour determination module 104 can be configured to segment the obtained image (possibly in an iterative process) for determining, with respect to one or more holes, data indicative of the contours of the top of the hole, and of the shape indicative of the bottom of the hole. The auxiliary module may assist in auxiliary operations, all as will be discussed in greater detail below.

Operation of systems 100, 101, 110, and the PMC(s) thereof, as well as the functional modules therein will be further detailed with reference to FIGS. 2-10.

In some cases, additionally to system 101, the examination system 100 can comprise one or more examination modules, such as, e.g., defect detection module and/or Automatic Defect Review Module (ADR) and/or Automatic Defect Classification Module (ADC), and/or an additional metrology-related module and/or other examination modules which are usable for examination of a semiconductor specimen. The one or more examination modules can be implemented as stand-alone computers, or their functionalities (or at least part thereof) can be integrated with the examination tool 120. In some cases, the output of system 101 such as, e.g., the images that are associated with data indicative of the contour of the bottom of the hole, can be provided to the one or more examination modules for further processing.

According to certain embodiments, system 101 can comprise a storage unit 122. The storage unit 122 can be configured to store any data necessary for operating system 101, e.g., data related to input and output of system 101, as well as intermediate processing results generated by system 101. By way of example, the storage unit 122 can be configured to store images of the specimen and/or derivatives thereof produced by the examination tool 120. Accordingly, the images can be retrieved from storage unit 122 and provided to the PMC 102 for further processing. The output of system 101 can be sent to storage unit 122 to be stored.

In some embodiments, system 100 can optionally comprise a computer-based Graphical User Interface (GUI) 124 which is configured to enable user-specified inputs related to system 101. For instance, the user can be presented with a visual representation of the specimen (for example, by a display forming part of GUI 124), including image data of the specimen. The user may be provided, through the GUI, with options of defining certain operation parameters. The user can also annotate the reference image via the GUI. The user may also view the operation results on the GUI.

In some cases, system 101 can be further configured to send, via I/O interface 126, the output data to one or more of the examination tools 120 and/or the one or more examination modules as described above, for further processing. In some cases, system 101 can be further configured to send certain output data to the storage unit 122, and/or external systems (e.g., Yield Management System (YMS) of a fabrication plant (FAB)).

Those versed in the art will readily appreciate that the teachings of the presently disclosed subject matter are not bound by the system illustrated in FIG. 1, and in particular not by the specified modules 104 and 106, and/or by the operations performed thereby, as described below with reference to FIGS. 2-10. Equivalent and/or modified functionality can be consolidated or divided in another manner, and can be implemented in any appropriate combination of software with firmware and/or hardware.

It is noted that the system illustrated in FIG. 1 can be implemented in a distributed computing environment, in which the aforementioned components and functional modules shown in FIG. 1 can be distributed over several local and/or remote devices, and can be linked through a communication network. For instance, the examination tool 120 and the system 101 can be located at the same entity (in some cases hosted by the same device), or distributed over different entities.

It is further noted that in some embodiments at least some of examination tools 120, storage unit 122, and/or GUI 124, can be external to the examination system 100 and operate in data communication with systems 100 and 101 via I/O interface 126. System 101 can be implemented as stand-alone computer(s) to be used in conjunction with the examination tools, and/or with the additional examination modules as described above. Alternatively, the respective functions of the system 101 can, at least partly, be integrated with one or more examination tools 120, thereby facilitating and enhancing the functionalities of the examination tools 120 in examination-related processes.

Although it is illustrated in FIG. 1, in some cases the functionalities of system 110 can be at least partly integrated with system 100. By way of example, the function modules of system 110 can be incorporated into the PMC 102 in system 101.

While not necessarily so, the process of operation of systems 101 and 100 can correspond to some or all of the stages of the methods described with respect to FIGS. 2-10. Likewise, the methods described with respect to FIGS. 2-10 and their possible implementations can be implemented by systems 101 and 100. It is therefore noted that embodiments discussed with respect to FIGS. 2-10 can also be implemented, mutatis mutandis, as various embodiments of the systems 101 and 100, and vice versa.

Attention is drawn to FIG. 2 illustrating schematically a semiconductor staircase 3DNAND specimen with a plurality of High Aspect Ratio (HAR) Vias mentioned above. Note that the specimen is illustrated for clarity in a translucent view for better understanding the structure of the specimen. Note that the latter 3DNAND staircase specimen is a non-limiting example of a semiconductor specimen to be inspected in accordance with certain embodiments of the presently disclosed subject matter. For clarity of explanation, the description will focus on the specific example of the 3DNAND staircase specimen, but those versed in the art will readily appreciate that the invention is not bound by this specific example, and it may apply, for instance, to an HAR process that requires CD measurement of the bottom.

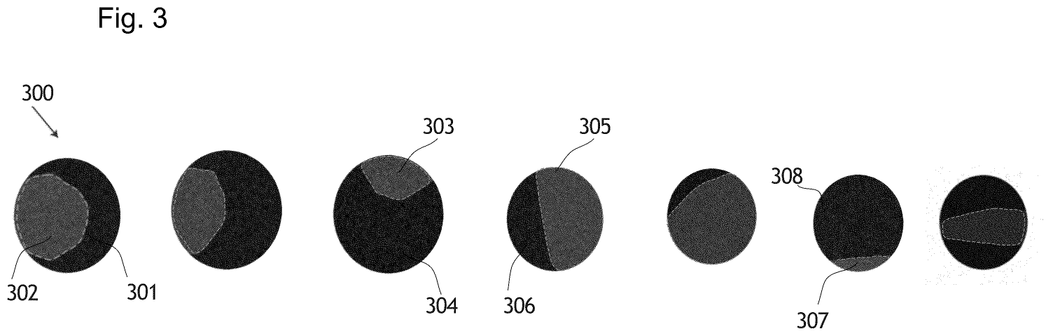

As shown, the 3DNAND specimen 200 includes a plurality of layers (of which only, e.g., two, 201 and 202, are marked). The layers may reside at different depths relative to the top surface 203 of the specimen. The 3DNAND staircase specimen further includes a plurality of holes (named also as “Vias”), of which 204 and 205 are marked. The Vias are typically characterized by a High Aspect Ratio (HAR) between Via depth and Via area (e.g., 1:40). The invention is, of course, not bound by this numerical example. The Vias penetrate through the specimen and end up in respective layers, for instance the bottom portion of Via 204 resides in (e.g. Tungsten) layer 201 and the bottom portion of Via 205 resides in (e.g. Tungsten) layer 202. Obviously, different holes may reside in different layers and the specified example of 204 and 205 is by no means limiting. Whereas the top portion of each hole can be of substantial identical shape (e.g., a circle), this is not the case for the bottom portion of the hole which may vary drastically from one hole to the other. See for instance FIG. 3 illustrating an inspection image or images that include a plurality of holes 300, each showing a different internal (brighter) shape, indicative of the bottom of the respective hole. Thus, for example, hole image 301 encloses a shape of a bottom of the hole 302 (indicated in brighter color than its vicinity) which is very different to the shape 303 (indicated in brighter color than its vicinity) of the bottom of hole 304. The same holds true for bottom 305 of hole 306 and bottom 307 of hole 308. The specified shapes (which are provided for illustrative purposes only) are indicative of the bottom of the respective holes, and the reason that they may be so different, one with respect to the other, stems, among others, from the HAR characteristic of the hole. The specified HAR characteristics can affect the etching process, leading to the specified shape difference between different Via bottoms.

It is important to characterize the shape of the respective hole to facilitate measuring the hole characteristics, e.g. bottom and/or top, all as will be explained in greater detail below. These measurement data may be used during various fabrication and other stages, as discussed e.g. in the background section above.

There are known in the art techniques which aim at identifying the shape of the bottom of the hole by defining a contour thereof, while relying on a shape characterizing model. However, considering the wide range variance between the various possible shapes, it is difficult to define a generic model that will conceive all possible shapes, and therefore prior art techniques that utilize shape characterizing models are not only possibly error-prone, but may also pose a computational overhead in an attempt to match the right model to the sought shape.

Measurements of hole characteristics that utilize at least the data indicative of the shape of the bottom of the hole, and possibly hole top hole walls, etc., may include at least one of the following:

CD, Area, and GL is calculated separately for top and bottom contours:
CD—fit contour to ellipse and calculate 2*sqrt (major_axis*minor_axis).
Area—fit contour to ellipse and calculate its area.
GL—grey level statistics such as average and std.
   Slant is between top and bottom COGs (Center of Gravity):
Direction—angle between the vector connecting COGs and X axis.
Length—Euclidian distance between COGs.

These measurements may be performed by any known per se examination tool. These data may serve for various processes as discussed above. The invention is of course not bound by these specific examples, and others may apply instead of or in addition to at least one of the specified measures.

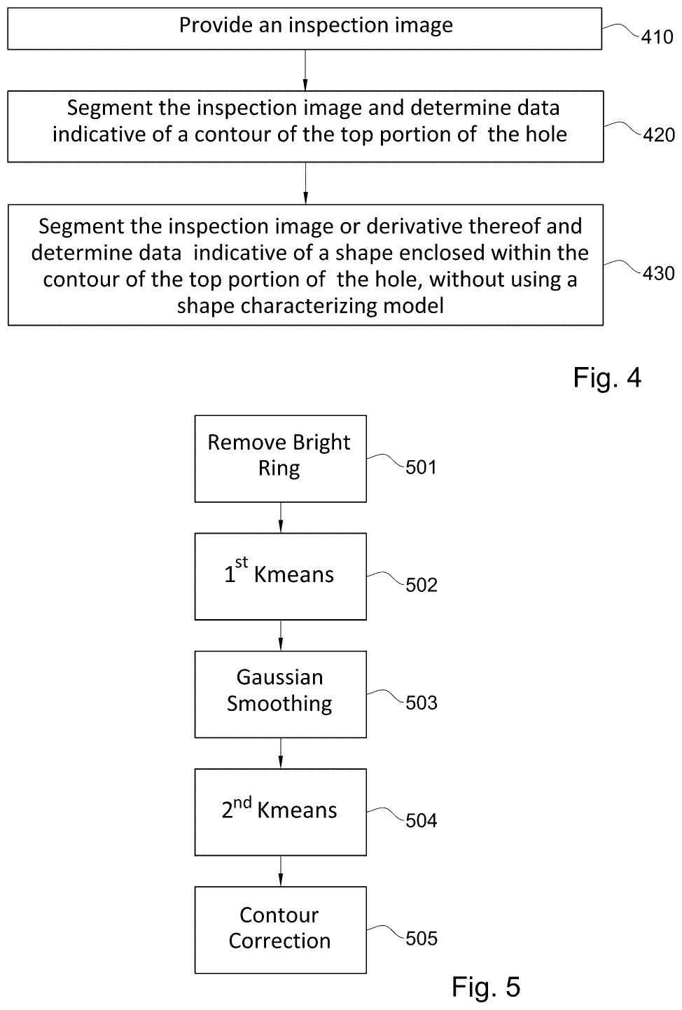

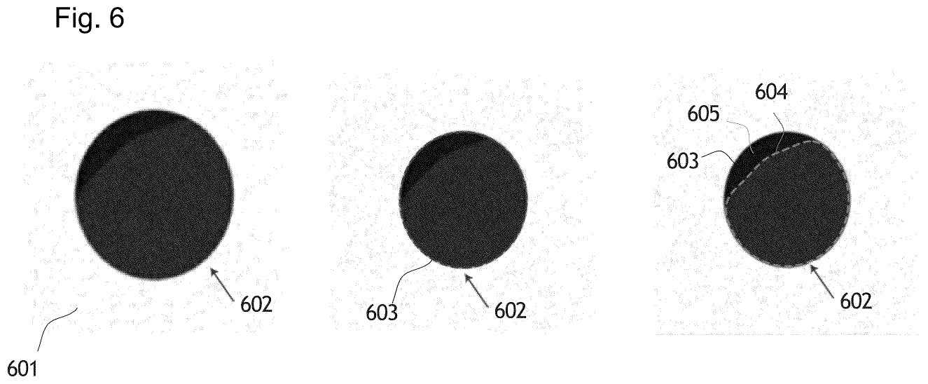

Bearing this in mind, attention is now drawn to FIG. 4 illustrating a generalized flowchart of a model-less sequence of operations, for segmenting an image and determining a contour of the shape of a bottom of a hole in a semiconductor specimen, in accordance with certain embodiments of the presently disclosed subject matter. Attention is also drawn to FIG. 6 depicting schematically the sequence of operations depicted in FIG. 4, in accordance with certain embodiments of the presently disclosed subject matter.

Thus, at step 410 an inspection image is provided indicative of at least one of said holes. The image may be obtained by the PMC 102 via the I/O interface 126, and may be acquired by the examination tool 120 during runtime examination of the specimen. The inspection image can result from various examination modality(s), such as, e.g., by an optical inspection tool, an electron beam tool, the specified VeritySEM tool etc., and the present disclosure is not limited by the specific examination modality used for acquiring the image. The inspection image may be indicative of one or more holes (Vias). The inspection image can comprise one or more perspective images captured from one or more perspectives of the examination tool.

Having obtained the inspection image, it may undergo processing (e.g., by segmentation and contour determination module 104 and Auxiliary module 106 of PMC 102). The image is processed with respect to at least one of said holes (see e.g., image 601 that includes hole 602). The processing steps include (420) segmenting the hole and determining data indicative of a contour of the top portion of the hole (see e.g. contour 603 of hole image 602). There are known in the art techniques for segmentation, e.g., GMM-Gaussian Mixture Model. The invention is obviously not bound by this example. Note that the data indicative of the contour data may be represented in many possible known per se manners, e.g. a numeric representation of the contour, an image that includes graphic indication of the contour (e.g., 603) (the latter may serve e.g., for outputting to a user through, say, GUI module 124)) and/or others.

Having identified the contour of the top of the hole, the inspection image or derivative thereof (e.g. the inspection image with an indication of the contour of the top of the hole) may be subjected to further processing as illustrated with reference to step 430, namely segment the inspection image or derivative thereof and determine data indicative of a contour of a shape of a bottom of the hole 604 enclosed within the contour of the top of the hole (603), without using a shape characterizing model. As may be recalled, the specified shape may vary drastically from one Via to the another, amongst others, because of the HAR of a typical Via which may affect the etching process and result in different shapes of the bottom of the hole. A non-limiting example of a specific sequence of operations for achieving the specified determination of data, indicative of the contour of the bottom of the hole, will be described in detail below. Note that the area 605 of the image that falls outside the contour of the shape (say 604) but is still enclosed within the contour of the top of the hole (say 603), may be indicative of the hole's walls.

The data indicative of the contour of shape of the bottom of the hole may facilitate examining the specimen (e.g., using various examination tool(s) 120) including measuring various characteristics of the hole and/or hole bottom, all as discussed above.

Note that before processing the specified inspection image (e.g. steps 420, 430), it may be necessary to localize it (in a known per se manner) for better processing the hole image (e.g., for processing each Via separately), as discussed above.

Note also that the specified procedure described above may be repeated with respect to other holes in case the inspection image includes more than one hole image.

Bearing this in mind, attention is now drawn to FIG. 5, illustrating a more specific flowchart of a model-less sequence of operations (e.g., performed by the segmentation and contour determination module 104 and auxiliary module 106 of PMC 102), for segmenting an image and determining a contour of a shape of a bottom of a hole in a semiconductor specimen, in accordance with certain embodiments of the presently disclosed subject matter.

The procedure in accordance with certain embodiments includes segmenting the inspection image, including, (possibly in iterations), classifying the image into at least two clusters of pixels having discernable pixel values, one with respect to the other, and determining the data indicative of the contour of said shape based on the pixel values of one of said clusters. Note that the difference in pixel values (grey level) stems from the fact that they represent distinct materials, for instance the Via's bottom may be made of Tungsten material (which may be manifested in brighter (say higher) pixel values, whereas the Via's walls may be made of Oxide silicon material (which may be manifested in darker (say lower) pixel values.

The process illustrated in FIG. 5 will now be described with reference to a specific segmentation technique, e.g., the K means technique. Note that the invention is not bound by the specified technique, and other techniques may be used, e.g. the known per se OTSU technique. Thus, after having determined data indicative of the contour of the top of the hole, the PMC may be configured to segment the image (the term encompasses also derivatives thereof), for instance by applying at least two iterations of the KMeans function, where K>2 in the first iteration, followed by a descending K in each next iteration, and K=2 in the last iteration.

Thus, by way of non-limiting example, in the first iteration K=4, in the second K=3 and in the third K=2, or by way of another non-limiting example, two iterations, where K=3 in the first iteration and K=2 in the second iteration.

This will lead to an image having at least two clusters of pixels characterized by discernable pixel values one with respect to the other, wherein the data indicative of the contour of said shape is determined based on the pixel values of one of said clusters.

The description with reference to FIG. 5 exemplifies the specific non-limiting example of only two iterations, where, in the first iteration K=3 (namely applying 3means technique, followed by K=2 iteration, namely applying 2means technique).

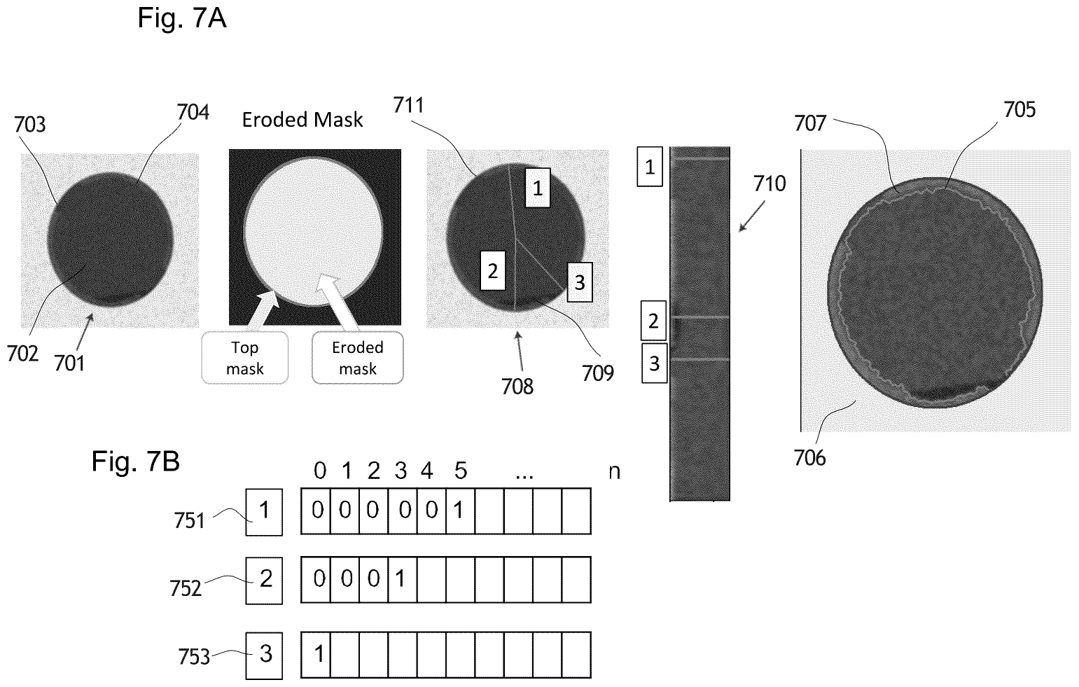

At the onset an initial optional step 501 is applied where data indicative of the determined contour of the top of the hole is processed, giving rise to a modified contour where peripheral pixels are excluded. The peripheral pixels are pixels at the periphery of the hole having “brighter” pixel values compared to pixels in their vicinity. Referring for a moment to FIG. 7A, the “brighter” pixels at the circumference of the hole (marked as 707), are excluded, such that they are not enclosed within the contour, thereby obtaining a modified contour.

Reverting to FIG. 5, this optional step may be advantageous in obtaining the resulting contour of the bottom of the hole at the following processing steps. The sequence of operations, that elaborate the step of exclusion peripheral “brighter” pixels, will be discussed in greater detail below with reference to FIG. 7.

Moving on with FIG. 5, the first Kmeans operation is applied (step 502), which, by this example, will give rise to an image with K clusters of pixels brackets (e.g., K=3).

Then, optionally a smoothing operation (e.g., by way of non-limiting example, Gaussian smoothing) will be applied (step 503) on the image.

Next (504), a second iteration of Kmeans operation is applied (say K=2) for obtaining a smaller number of clusters than the previous iteration.

Finally (505), an optional morphological operation, e.g., contour correction operation, may be applied, as will be explained in greater detail below.

It is thus noted that, in accordance with certain embodiments, in each iteration the Kth value is reduced, giving rise to a lesser number of clusters compared to the previous iteration, until two clusters are obtained, where one of them represents the shape of the bottom of the hole.

Before moving on to exemplify the images obtained as a result of applying the Kmeans operations, those versed in the art will readily appreciate that no shape characterizing model has been utilized. Intuitively, a shape characterizing model aims at modeling given known shapes or shape clusters that may be used by an examination tool e.g., for measurements, classification etc. to classify a sought shape. As discussed in detail above, because of the significant variance between possible shapes that represent corresponding bottoms of different Vias, it is difficult and error prone to define a shape characterizing model that will embrace all possible bottom shapes.

Note that whereas FIG. 5 illustrates three auxiliary operations (steps 501, 503 and 505)—all possibly implemented in auxiliary tool 106 of PMC 102, the invention is not bound by utilizing any of these auxiliary operations, and, accordingly, one or more of them may be obviated or replaced by a different auxiliary operation not disclosed herein. Or, auxiliary operations not disclosed herein, may be added to some or all of the auxiliary operations disclosed with reference to FIG. 5. Note also that this consideration may be applied to other segmentation techniques, not necessarily the specified K means operation, mutatis mutandis.

Bearing this in mind, attention is drawn to FIG. 7A, illustrating schematically a flowchart of removing a bright ring in an image, in accordance with certain embodiments of the presently disclosed subject matter (step 501 of FIG. 5). As specified above, this auxiliary operation is optional and aims at improving the result of the following segmentation steps, and may be implemented in, say, auxiliary tool 106 of PMC 102.

The flowchart of FIG. 7A is illustrated, for clarity, as a sequence of images, Thus, image 701 depicts a hole 702 and a contour 703 indicative of the top portion of the hole. As illustrated, image 701 includes at its periphery a partial ring of pixels 704 which are brighter (in grey level value) than the pixels in their vicinity. This phenomenon may be encountered, e.g. when the top contour is not tight enough to the via, and a kind of bright ring appears. In accordance with certain embodiments, the existence of this “ring” (being an example of peripheral external brighter pixels) may adversely affect the accuracy of clustering the inner shape indicative of the bottom of the hole. Thus, it is desired to obtain data indicative of a modified contour that represent the top portion of the hole, while not including these “brighter” pixels. The modified contour 705 is depicted in image 706 where the specified “bright pixels” 707 are excluded.

Before applying the next step, a top mask and an eroded mask may be placed. Note that, typically, an eroded mask may be used to erode the shape of the top contour, to decide on which pixels the required percentile will be calculated. The utilization of masks and their functionality is generally known per se.

One possible technique of obtaining the modified contour is exemplified with reference to image 708 and the corresponding arrays in FIG. 7B. Thus, by this non-limiting example, image 701 (possibly after applying the masks) is sampled at distinct radii. For simplicity, one slice 709 is depicted in image 708 and is bordered by separation lines (referred to interchangeably as radii), indicated as “2” and “3”. Obviously, the specified graphic representation separating lines are only an example, and by another non-limiting example the radii may be represented as data indicative thereof (e.g., an angle of the separation line relative to, say, a reference angle “0 degrees”—not shown) may be utilized. Also, the number of radii may vary, depending upon the application.

Moving on with FIG. 7B, assume that the entire hole depicted in image 708 includes plurality radii such as 709. The circular hole 708 may then be mapped to rectangular 710 where separation lines “1”, “2” and “3” are placed in rectangular 710 in corresponding locations to their locations on the hole in image 708 (starting with “1” and moving counter clockwise to hit separation lines “2” and then “3”).

As will be explained below, each separation line is processed to identify the outmost bright pixels (which should be removed), and thereafter a modified contour can be depicted according to the inner “non bright” pixels of each separation line. Thus, starting with, say, separation line “1”, in order to “remove” the outmost bright pixels residing at the external part thereof, a configurable threshold value is set, say for 8 bit representation (representing grey level values of 0 to 255), and the threshold is set to, say, 210. This threshold signifies that any pixel whose value exceeds 210 (meaning it is “bright”) will be removed. (All numbers are provided for illustrative purposes and are by no means binding). Before moving on, note that each separation line may be associated with corresponding auxiliary array of n cells (see e.g., arrays 751, 752, and 753 in FIG. 7B, that correspond to separation lines “1”, “2” and “3”, respectively). Thus, by this example, Cell #0 in array 751 indicates the outermost pixel of separation line “1”, and Cell #n−1 indicates the innermost pixel of separation line “1”. The same holds true for arrays 752 and 753 with respect to separation lines “2” and “3” respectively. Obviously there may be additional separation lines (not depicted in hole image 708).

Moving on with the example of separation line “1”, the pixel value in cell #0 (the outmost pixel) is compared to the threshold. Assuming that its value exceeds the threshold (i.e., in the latter example, its grey level value is higher than 210, namely it is a “bright” pixel), the cell value is set to “0” indicating that this pixel should be removed (i.e. it is a “brighter” peripheral pixel). Then, the next pixel in cell #1 is processed, assuming also that its value exceeds the threshold, and therefore it is also set to “0” (i.e., it should also be removed). This process is continued until encountering the first location that signifies a pixel whose pixel value drops below the threshold value 210. Assume that this pixel is found in cell #5 which is then set to “1”. At this stage the processing of separation line “1” is completed to indicate that the five outmost “brighter” pixels (locations 0-4) should be removed. This process is repeated for separation line “2”, resulting in 3 pixels to be removed (see locations 0-2 in array 752) and for separation line “3” resulting in no pixels to be removed (see value “1” in location “1” in array 753). The same procedure is repeated for all separation lines (not shown in the Figs.). The modified contour can now be constructed based on the non-removed pixels for each separation line (e.g. the modified contour is composed of the 6^{th} pixel in line “1”, the 4^{th} pixel in separation line “2”, and the first pixel in separation line “3”, and so forth for all other separation lines not shown in the Figs., resulting in a modified contour 705 which excludes the bright pixels 707.

The utilization of separation lines as well as auxiliary arrays, as discussed above, is of course a non-limiting example of a proposed procedure for removing the external bright pixels. Note that, while, for clarity, the description focused on “bright” or “brighter” pixels (corresponding to, say, grey level values that exceed a given threshold), those versed in the art should readily note that the term “bright” or “brighter” embraces also an equivalent scenario, say by non-limiting example “bright pixels” are represented as “dark pixels”, and the sought values for removal are those that drop below a given threshold. For instance, with the example of FIG. 7, the external excluded pixels 707 have, each, a pixel value that represents a grey level value of “darker” pixels than the grey level value of pixels in their vicinity (that are enclosed in the modified contour 705).

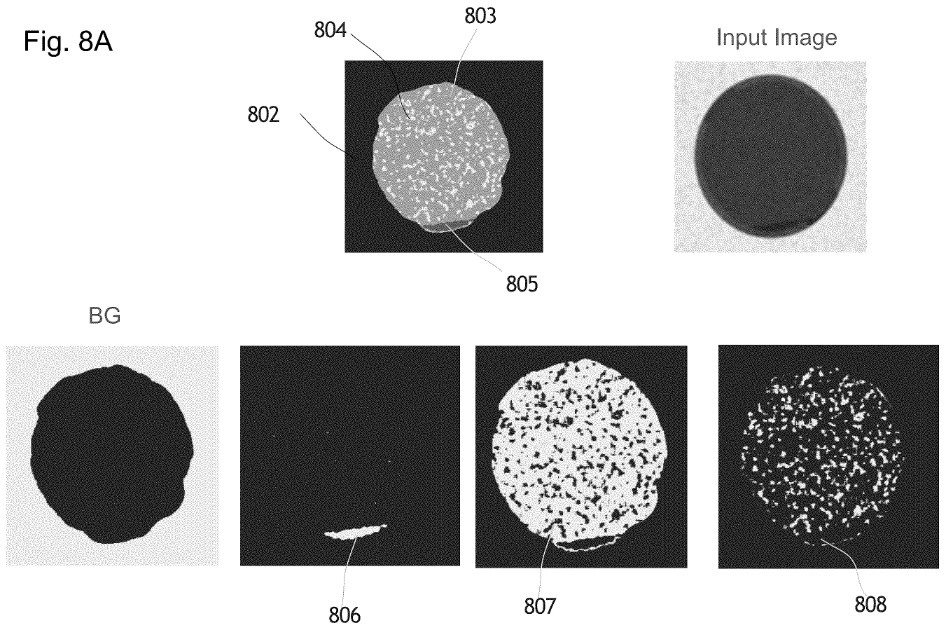

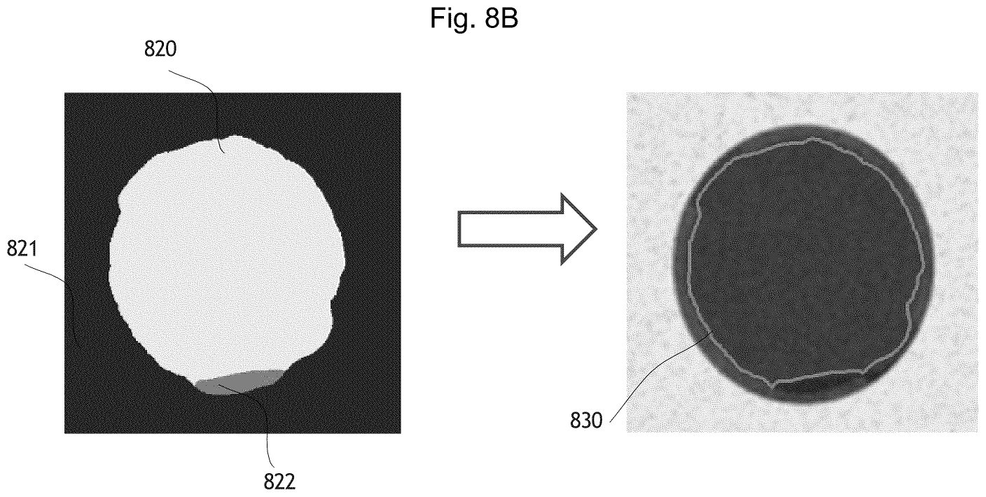

Having described a non-limiting example of removing external bright pixels, attention is drawn to FIGS. 8A-B illustrating schematically a plurality of images, obtained as a result of applying first and second Kmeans iterations, in accordance with certain embodiments of the presently disclosed subject matter. Note that the invention is not bound by the specified known per se Kmeans technique for segmenting the image. As specified, these operations may be implemented in, say, segmentation tool 106 of PMC 102.

Thus, as shown in FIG. 8A, the input image (after having been subjected to determination of a contour indicative of the top portion of the hole and possibly removal of external “bright pixels”, as discussed in detail above), is fed to the Kmeans function (by this example K=3), resulting in three clusters of pixels having in each cluster discernable pixel values, one with respect to the other. The resulting image is shown in 802 with three populations that correspond to the three clusters 803, 804, and 805, respectively. The distinct populations are shown, separately, for clarity, in images 806, 807, and 808. The three clusters image may be then fed to 2means (k=2) operations (see FIG. 8B), reducing it to two (or more) clusters having discernable pixel values, one with respect to the other. As shown, an output image that results from the 2Means operation includes the surface 821, the wall 822, and the bottom 820 (by this example 3 clusters) resulting (after the contour segmentation) in contour 830. The latter is indicative of the bottom 820 of the hole.

Note that the Kmeans (k=2) is accurate by virtue of the preceding K>2 iteration that reduced the number of clusters, facilitating better results of the following Kmeans (K=2) operation. As shown in FIG. 8B, once two clusters have been determined, it is possible to define data indicative of the shape 830 and the contour of the shape that represents the bottom of the hole, not withstanding its HAR, and while not utilizing a shape characterizing model.

As advised, the invention is bound neither by the specified Kmeans function, nor by the number of iterations.

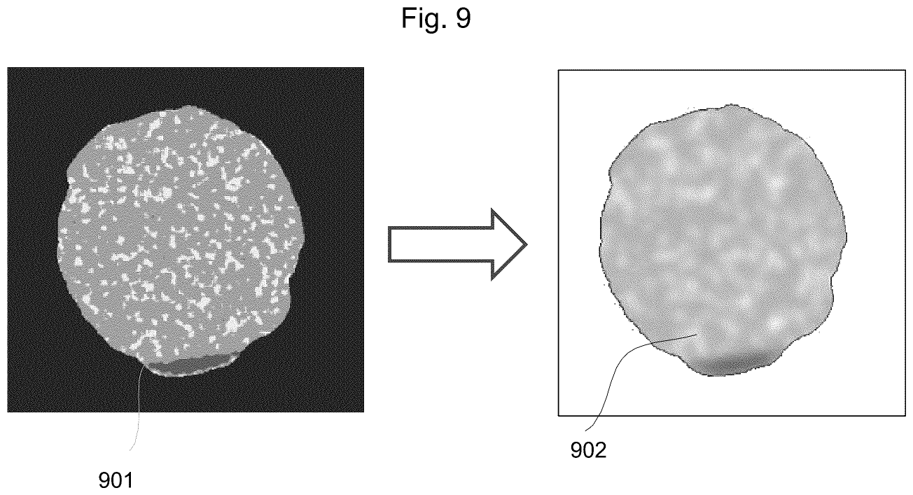

In accordance with certain embodiments, a known smoothing procedure may be applied between one or more of the iterations utilizing, e.g., the Gaussian smoothing, shown e.g., with reference to FIG. 9. The latter illustrates applying the smoothing function between the 3kmeans and 2kmeans operations. Image 901 is the input (fed as output of the 3kMeans operation) which may include integer representation of the three clusters (e.g., values 1, 2, and 3 representing the respective three clusters) and in the resulting smoothened image (see 902). Each pixel may be represented as e.g., a float number ranging from 1-3 (rather than integers), allowing better categorization into two binary clusters in the following 2Kmeans operation. The smoothened image will then be fed to the 2means module for obtaining two clusters in the manner specified, which may produce better results in view of the smoothing operation.

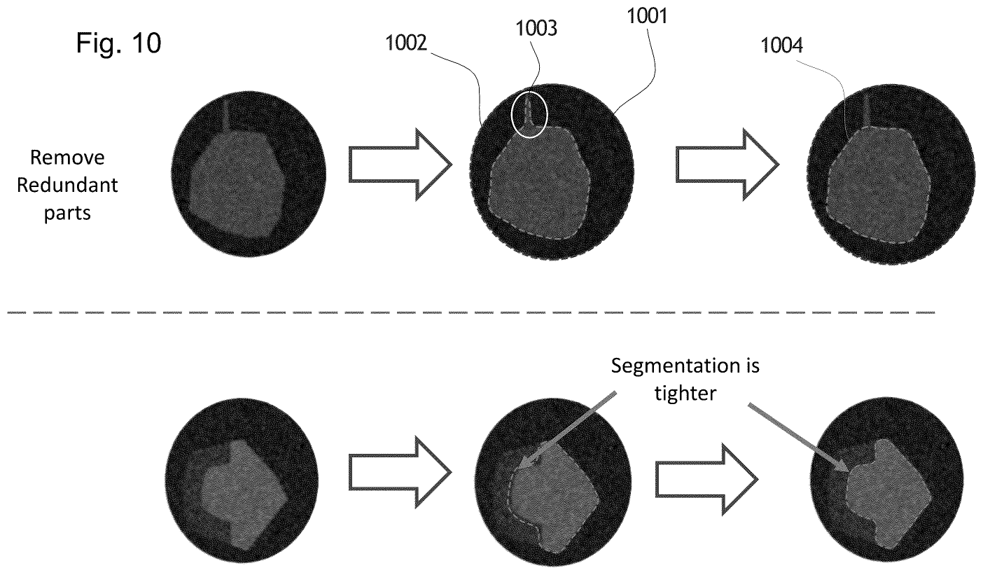

Turning now to FIG. 10, it illustrates schematically an image indicative of a shape of the bottom of a hole in a semi-conductor specimen, obtained as a result of applying a morphological operation, e.g., contour correction operation including removal of redundant parts of the contour, in accordance with certain embodiments of the presently disclosed subject matter. Note that morphological operation(s) may be part of e.g., expansion or shrinking of the contour shape.

Thus, following determination of data indicative of the shape and the contour of the bottom of the hole, one or more morphological operations may be applied, e.g., contour correction operation. By this example the contour may modify the contour shape or and/or size e.g., by expanding or shrinking the shape, or better represent the bottom of the hole. The latter may be performed by the auxiliary module 106 of PMC 102.

As shown by way of non-limiting example, the contour of the shape 1003 (which may be found following the 2means operation by known per se function, may include redundant section 1003 that is not likely to be part of the shape that represents the bottom of the hole, and therefore it is removed, giving rise to corrected shape and contour (e.g. 1004).

By yet another example, the shape is shrunk (possibly utilizing morphological operations), e.g. as a result of a user decision according to the data (for instance removing more pixels which should have been classified as “bright” or vice versa (in case of expansion).

It is to be noted that examples illustrated in the present disclosure, such as, e.g., the examples of input and resulting images, various processing techniques, numeral values etc., are merely illustrated for exemplary purposes, and should not be regarded as limiting the present disclosure in any way. Other appropriate examples/implementations can be used in addition to, or in lieu of the above.

Among advantages of certain embodiments of the subject matter as described herein, is providing data indicative of accurate shapes of the bottom of holes in semiconductor specimens, facilitating more accurate examination and improved processes, such as the semiconductor fabrication process.

In the detailed description, numerous specific details are set forth in order to provide a thorough understanding of the disclosure. However, it will be understood by those skilled in the art that the presently disclosed subject matter may be practiced without these specific details. In other instances, well-known methods, procedures, components, and circuits have not been described in detail so as not to obscure the presently disclosed subject matter.

Unless specifically stated otherwise, as apparent from the discussions, it is appreciated that throughout the specification discussions utilizing terms such as “examining”, “obtaining”, “providing” “acquiring”, “identifying”, “determining”, “localizing”, “processing”, “segmenting”, “utilizing”, “applying”, “generating”, “performing”, “measuring”, “associating”, “classifying”, “segmenting”, or the like, refer to the action(s) and/or process(es) of a computer that manipulate and/or transform data into other data, said data represented as physical, such as electronic, quantities, and/or said data representing the physical objects. The term “computer” should be expansively construed to cover any kind of hardware-based electronic device with data processing capabilities as described, e.g., with reference to FIG. 1.

The processor referred to in the current disclosure can represent one or more general-purpose processing devices such as a microprocessor, a central processing unit, or the like. More particularly, the processor may be a complex instruction set computing (CISC) microprocessor, a reduced instruction set computing (RISC) microprocessor, a very long instruction word (VLIW) microprocessor, a processor implementing other instruction sets, or processors implementing a combination of instruction sets. The processor may also be one or more special-purpose processing devices such as an application specific integrated circuit (ASIC), a field programmable gate array (FPGA), a digital signal processor (DSP), a network processor, or the like. The processor is configured to execute instructions for performing the operations and steps discussed herein.

The memory referred to herein can comprise a main memory (e.g., read-only memory (ROM), flash memory, dynamic random access memory (DRAM), such as synchronous DRAM (SDRAM) or Rambus DRAM (RDRAM), etc.), and a static memory (e.g., flash memory, static random access memory (SRAM), etc.).

The terms “non-transitory memory” and “non-transitory storage medium” used herein should be expansively construed to cover any volatile or non-volatile computer memory suitable to the presently disclosed subject matter. The terms should be taken to include a single medium or multiple media (e.g., a centralized or distributed database, and/or associated caches and servers) that store the one or more sets of instructions. The terms shall also be taken to include any medium that is capable of storing or encoding a set of instructions for execution by the computer and that cause the computer to perform any one or more of the methodologies of the present disclosure. The terms shall accordingly be taken to include, but not be limited to, a read only memory (“ROM”), random access memory (“RAM”), magnetic disk storage media, optical storage media, flash memory devices, etc.

The term “specimen” used in this specification should be expansively construed to cover any kind of physical objects or substrates, including wafers, masks, reticles, and other structures, combinations and/or parts thereof used for manufacturing semiconductor integrated circuits, magnetic heads, flat panel displays, and other semiconductor-fabricated articles. A specimen is also referred to herein as a semiconductor specimen and can be produced by manufacturing equipment executing corresponding manufacturing processes.

The term “examination” used in this specification should be expansively construed to cover any kind of operations related to defect detection, defect review, and/or defect classification of various types, segmentation, and/or metrology operations during and/or after the specimen fabrication process. Examination is provided by using non-destructive examination tools during or after manufacture of the specimen to be examined. By way of non-limiting example, the examination process can include runtime scanning (in a single or in multiple scans), imaging, sampling, detecting, reviewing, measuring (including e.g., measurements of characteristics of specimen holes and hole's bottom), classifying and/or other operations provided with regard to the specimen or parts thereof, using the same or different inspection tools. Likewise, examination can be provided prior to manufacture of the specimen to be examined, and can include, for example, generating an examination recipe(s) and/or other setup operations. It is noted that, unless specifically stated otherwise, the term “examination” or its derivatives used in this specification are not limited with respect to resolution or size of an inspection area. A variety of non-destructive examination tools includes, by way of non-limiting example, scanning electron microscopes (SEM), atomic force microscopes (AFM), optical inspection tools, etc.

The term “shape characterizing model” used in this specification should be expansively construed to cover any kind of model that characterizes geometrical shapes that is obtained e.g., from a-priori design, drawing(s) (e.g., by a user or computer), and used for determining a sought shape or shapes (e.g., the shape of the bottom of the hole). A-priori in this context means that first the model is prepared, and then the model is used for determining the sought shape.

In the structure of a vertical NAND, memory cells are stacked one on top each other, and each one is activated by its corresponding Word-line (WL). The connections to the WLs are arranged in a staircase-like structure, enabling access to each WL level individually. The contact holes are etched through silicone oxide, landing on the Tungsten line staircase, creating the connection between the Word-lines in different layers. The term HAR should be construed as the ratio between the width and length of the hole, or equivalent thereof. The term Via should be construed to include a vertical hole between two or more adjacent layers to perform an electrical connection.

It is appreciated that, unless specifically stated otherwise, certain features of the presently disclosed subject matter, which are described in the context of separate embodiments, can also be provided in combination in a single embodiment. Conversely, various features of the presently disclosed subject matter, which are described in the context of a single embodiment, can also be provided separately, or in any suitable sub-combination. In the following detailed description, numerous specific details are set forth in order to provide a thorough understanding of the methods and apparatus.

Note that in accordance with certain embodiments, the order of computational stages described herein with reference to the drawings is not necessarily binding. For instance, the order of steps may be changed, steps may be modified or deleted, and/or other steps may be added instead of or in addition to those disclosed herein.

It is to be understood that the present disclosure is not limited in its application to the details set forth in the description contained herein or illustrated in the drawings.

It will also be understood that the system according to the present disclosure may be, at least partly, implemented on a suitably programmed computer. Likewise, the present disclosure contemplates a computer program being readable by a computer for executing the method of the present disclosure. The present disclosure further contemplates a non-transitory computer-readable memory tangibly embodying a program of instructions executable by the computer for executing the method of the present disclosure.

The present disclosure is capable of other embodiments and of being practiced and carried out in various ways. Hence, it is to be understood that the phraseology and terminology employed herein are for the purpose of description and should not be regarded as limiting. As such, those skilled in the art will appreciate that the conception upon which this disclosure is based may readily be utilized as a basis for designing other structures, methods, and systems for carrying out the several purposes of the presently disclosed subject matter.

Those skilled in the art will readily appreciate that various modifications and changes can be applied to the embodiments of the present disclosure as hereinbefore described without departing from its scope, defined in and by the appended claims.

1. A system for examining a semiconductor specimen comprising a plurality of layers at respective different depths, and a plurality of holes, each hole having a top portion at the surface of said specimen and a bottom portion accommodated in one of said layers, the system comprising a processing and memory circuitry (PMC) configured to:
a. provide an inspection image indicative of at least one of said holes;
b. process at least one hole image in said inspection image, including:
i. segment the inspection image and determine data indicative of a contour of the top portion of the hole;
ii. segment the inspection image or derivative thereof and determine data indicative of a contour of a shape of the bottom of said hole enclosed within the contour of the top of the hole; wherein said segmenting includes classifying the image into at least two clusters of pixels having discernable pixel values one with respect to the other, and determining the data indicative of the contour of said shape based on the pixel values of one of said clusters;
thereby facilitating examining of the specimen including utilizing at least the data indicative of the contour of the shape of the bottom of said hole, for measurements of characteristics of at least the hole bottom.

2. The computerized system according to claim 1, wherein said semiconductor specimen is a staircase 3DNAND, and wherein said hole is a High Aspect Ratio (HAR) Via, and wherein said bottom portion is accommodated in a Tungsten layer of said specimen.

3. The computerized system according to claim 1, wherein the segmenting stipulated in said (b) (ii), does not use a shape characterizing model.

4. The computerized system according to claim 1, wherein said PMC is configured in said (ii) to segment the image, including: applying at least two iterations of KMeans function, where K>2 in the first iteration, followed by a descending K in each next iteration, and K=2 in the last iteration, giving rise to an image having at least two clusters of pixels characterized by discernable pixel values, one with respect to the other, wherein the data indicative of the contour of said shape is determined based on the pixel values of one of said clusters.

5. The computerized system according to claim 4, including two iterations, wherein K=3 in the first iteration, and K=2 in the second iteration.

6. The computerized system according to claim 4, wherein said PMC is further configured to apply a smoothing operation between at least two of said iterations.

7. The computerized system according to claim 4, wherein said PMC is further configured to apply at least one morphological operation following said last iteration, for obtaining data indicative of a different contour representing a corrected shape of the bottom of said hole.

8. The computerized system according to claim 4, wherein said PMC is further configured to determine data indicative of the contour of the top portion of said hole, such that peripheral pixels are excluded, and then applying said at least two iterations; wherein said peripheral pixels are pixels at the periphery of the hole having pixel values indicative of brighter pixels compared to pixels in their vicinity.

9. The computerized system according to claim 1, wherein said shape characterizing model characterizes geometrical shapes obtained from at least an a-priori design or drawing, and used for determining a sought shape or shapes.

10. The computerized system according to claim 1, further comprising measuring at least one of the following characteristics of hole top or bottom:
CD—fit contour to ellipse and calculate 2*sqrt (major_axis*minor_axis);
Area—fit contour to ellipse and calculate its area;
GL—grey level statistics including average and std;
slant is between top and bottom COGs (Center of Gravity);
Direction—angle between the vector connecting COGs and X axis;
Length—Euclidian distance between COGs.

11. A computerized method for examining a semiconductor specimen comprising a plurality of layers at respective different depths and a plurality of holes, each hole having a top portion at the surface of said specimen and a bottom portion accommodated in one of said layers, the method comprising by a processor and memory circuitry (PMC):
a. providing an inspection image indicative of at least one of said holes;
b. processing at least one hole image in said image, including:
i. segmenting the inspection image and determining data indicative of a contour of the top portion of the hole;
ii. segmenting the inspection image or derivative thereof and determining data indicative of a contour of a shape enclosed within the contour of the top of the hole, without using a shape characterizing model;
thereby facilitating examining of the specimen including utilizing at least the data indicative of the contour of the shape of the bottom of said hole, for measurements of characteristics of at least the hole bottom.

12. The computerized method according to claim 11, wherein said semiconductor specimen is a staircase 3DNAND, and wherein said hole is a High Aspect Ratio (HAR) Via, and wherein said bottom portion is accommodated in a Tungsten layer of said specimen.

13. The computerized method according to claim 11, wherein said (ii) includes segmenting the image including classifying the image into at least two clusters of pixels having discernable pixel values, one with respect to the other, and determining the data indicative of the contour of said shape based on the pixel values of one of said clusters.

14. A non-transitory computer readable storage medium tangibly embodying a program of instructions that, when executed by a computer, cause the computer to perform a method for examining a semiconductor specimen comprising a plurality of layers at respective different depths and a plurality of holes, each hole having a top portion at the surface of said specimen and a bottom portion accommodated in one of said layers, the method comprising:
a. providing an inspection image indicative of at least one of said holes;
b. processing at least one hole image in said image, including:
i. segmenting the inspection image and determining data indicative of a contour of the top portion of the hole;
ii. segmenting the inspection image or derivative thereof and determining data indicative of a contour of a shape enclosed within the contour of the top of the hole, without using a shape characterizing model,
thereby facilitating examining of the specimen including utilizing at least the data indicative of the contour of the shape of the bottom of said hole, for measurements of characteristics of at least the hole bottom.

15. The non-transitory computer readable storage medium of claim 14, wherein said semiconductor specimen is a staircase 3DNAND, and wherein said hole is a High Aspect Ratio (HAR) Via, and wherein said bottom portion is accommodated in a Tungsten layer of said specimen.

16. The non-transitory computer readable storage medium of claim 14, wherein said (ii) includes segmenting the image, including classifying the image into at least two clusters of pixels having discernable pixel values one with respect to the other, and determining the data indicative of the contour of said shape based on the pixel values of one of said clusters.

17. The non-transitory computer readable storage medium of claim 14, wherein said (ii) includes: segmenting the image including: applying at least two iterations of KMeans function, where K>2 in the first iteration, followed by a descending K in each next iteration, and K=2 in the last iteration, giving rise to an image having at least two clusters of pixels characterized by discernable pixel values one with respect to the other, wherein the data indicative of the contour of said shape is determined based on the pixel values of one of said clusters.

18. The non-transitory computer readable storage medium of claim 17, including two iterations, wherein K=3 in the first iteration, and K=2 in the second iteration.

19. The non-transitory computer readable storage medium of claim 14, wherein said shape characterizing model characterizes geometrical shapes obtained from at least an a-priori design or drawing, and used for determining a sought shape or shapes.

20. The non-transitory computer readable storage medium of claim 14, wherein the method further comprising measuring at least one of the following characteristics of the hole top or hole bottom:
CD—fit contour to ellipse and calculate 2*sqrt (major_axis minor_axis);
Area—fit contour to ellipse and calculate its area;
GL—grey level statistics including average and std;
slant is between top and bottom COGs (Center of Gravity):
Direction—angle between the vector connecting COGs and X axis;
Length—Euclidian distance between COGs.
